(19) United States
(12) Patent Application Publication
(10) Pub. No.: US 2025/0228088 A1
(43) Pub. Date: Jul. 10, 2025

(54) DISPLAY DEVICE

(71) Applicant: Samsung Display Co., Ltd., Yongin-si (KR)

(72) Inventors: JEONGHYUN LEE, Yongin-si (KR); PIL GYU KANG, Yongin-si (KR); HYUN-CHUL PARK, Yongin-si (KR); EUNA YU, Yongin-si (KR); HANUL LEE, Yongin-si (KR); SANGCHEON HAN, Yongin-si (KR)

(21) Appl. No.: 18/929,379

(22) Filed: Oct. 28, 2024

(30) Foreign Application Priority Data
Jan. 8, 2024 (KR) 10-2024-0002703

(51) Int. Cl. H10K 59/131; H10K 59/126; H10K 59/35

(52) U.S. Cl. CPC H10K 59/131; H10K 59/126; H10K 59/35

(57) ABSTRACT

A display device includes a pixel having a transmissive area to transmit external light, and a non-transmissive area to block external light and including an emissive area, a first non-emissive area between adjacent emissive areas, and a second non-emissive area between adjacent transmissive areas, a driving scan line connected to the pixel, a sensing scan line connected to the pixel, and a horizontal voltage line connected to the pixel, wherein, in the first non-emissive area, the driving scan line, the sensing scan line, and the horizontal voltage line are spaced from each other at a first interval, and wherein, in the second non-emissive area, the driving scan line, the sensing scan line, and the horizontal voltage line either overlap each other or are spaced from each other at a second interval that is smaller than the first interval.

### CROSS-REFERENCE TO RELATED APPLICATIONS

The present application claims priority to, and the benefit of, Korean Patent Application No. 10-2024-0002703 filed on Jan. 8, 2024, in the Korean Intellectual Property Office, the disclosures of which are incorporated by reference herein in their entireties.

### BACKGROUND

### 1. Field

Embodiments of the present disclosure described herein relate to a transparent display device.

### 2. Description of the Related Art

Among display devices, an emissive display device displays an image using a light-emitting diode that generates light by recombination of electrons and holes. The emissive display device has a high response speed and is driven with low power consumption.

The emissive display device includes a display panel in which pixels connected to data lines and scan lines are arranged. In general, each of the pixels includes a light-emitting diode, and a pixel circuit unit for controlling the amount of current flowing to the light-emitting diode. The pixel circuit unit controls the amount of current flowing through the light-emitting diode in response to a data signal. At this time, light having a corresponding luminance is generated depending on the amount of current flowing through the light-emitting diode.

The emissive display device may have transmission characteristics by employing a transparent display panel. In the transparent display panel, light transmitting areas may be defined in respective pixels to transmit light. Accordingly, a user does not only visually recognize an image displayed through the pixels of the 1 display panel, but may also visually recognize an object behind the display panel or an image by light transmitting through the light-emitting areas.

### SUMMARY

Embodiments of the present disclosure provide a display device with improved transmittance.

According to one or more embodiments, a display device includes a pixel having a transmissive area configured to transmit external light, and a non-transmissive area configured to block external light and including an emissive area, a first non-emissive area between two adjacent emissive areas, and a second non-emissive area between two adjacent transmissive areas, a driving scan line connected to the pixel, and extending in a first direction, a sensing scan line connected to the pixel, and extending in the first direction, and a horizontal voltage line connected to the pixel, and extending in the first direction, wherein, in the first non-emissive area, the driving scan line, the sensing scan line, and the horizontal voltage line are spaced from each other at a first interval in a second direction crossing the first direction, and wherein, in the second non-emissive area, the driving scan line, the sensing scan line, and the horizontal voltage line either overlap each other or are spaced from each other at a second interval in the second direction that is smaller than the first interval.

The first non-emissive area may include a first sub-area where the driving scan line, the sensing scan line, and the horizontal voltage line are spaced from each other at the first interval, and a second sub-area where the driving scan line, the sensing scan line, and the horizontal voltage line either overlap each other or are spaced from each other at the second interval.

The second sub-area may be between the first sub-area and the second non-emissive area.

1 The horizontal voltage line may be between the driving scan line and the sensing scan line in plan view, wherein a separation distance between the driving scan line and the sensing scan line is greater than a width of the horizontal voltage line.

The horizontal voltage line may be on a different layer than the driving scan line and the sensing scan line.

A gate pattern layer may include the driving scan line and the sensing scan line, wherein a data pattern layer includes the horizontal voltage line.

The horizontal voltage line may be between the driving scan line and the sensing scan line in plan view, wherein a separation distance between the driving scan line and the sensing scan line is less than a width of the horizontal voltage line.

The display device may further include a first voltage line connected to the pixel, and extending in the second direction, and a second voltage line connected to the pixel, extending in the second direction, and spaced from the first voltage line in the first direction, wherein the horizontal voltage line is connected to the first voltage line or the second voltage line.

The horizontal voltage line may be between the driving scan line and the sensing scan line in plan view, wherein the driving scan line includes a first line portion on a same layer as the horizontal voltage line in the first non-emissive area, and a second line portion on a different layer from the horizontal voltage line in the second non-emissive area, and wherein the sensing scan line includes a third line portion on a same layer as the horizontal voltage line in the first non-emissive area, and a fourth line portion on a different layer from the horizontal voltage line in the second non-emissive area.

A separation distance between the second line portion and the fourth line portion may be less than a separation distance between the first line portion and the third line portion.

1 The first line portion may be connected with the second line portion through a first contact hole, wherein the third line portion is connected with the fourth line portion through a second contact hole.

The pixel may include a first sub-pixel configured to output light of a first color, a second sub-pixel configured to output light of a second color, and a third sub-pixel configured to output light of a third color.

The display device may further include a first data line connected to the first sub-pixel, and extending in the second direction, a second data line connected to the second sub-pixel, and extending in the second direction, and a third data line connected to the third sub-pixel, and extending in the second direction, wherein the first data line, the second data line, and the third data line overlap the first non-emissive area.

The first data line, the second data line, and the third data line may be on a different layer than the driving scan line, the sensing scan line, and the horizontal voltage line.

The driving scan line and the horizontal voltage line may be on a different layer than the first data line, the second data line, and the third data line, wherein the sensing scan line includes a third line portion in the first non-emissive area on a same layer as the driving scan line, and a fourth line portion in the second non-emissive area on a same layer as the first data line, as the second data line, and as the third data line, and wherein the third line portion is connected with the fourth line portion through a second contact hole.

The driving scan line, the fourth line portion of the sensing scan line, and the horizontal voltage line may overlap each other.

The display device may further include a first voltage line connected to the pixel, and extending in the second direction, and a second voltage line connected to the pixel, extending in the second direction, and spaced from the first voltage line in the 1 first direction, wherein the first voltage line and the second voltage line are on a same layer as the first data line, the second data line, and the third data line.

The display device may further include a first connection line connecting the driving scan line to the first sub-pixel, the second sub-pixel, and the third sub-pixel, and a second connection line connecting the sensing scan line to the first sub-pixel, the second sub-pixel, and the third sub-pixel.

The first and second connection lines may be on a same layer as the driving scan line and the sensing scan line, wherein the first and second connection lines are on a different layer than the horizontal voltage line.

According to one or more embodiments, a display device includes a base layer, a buffer layer above the base layer, an inter insulating layer above the buffer layer, a pixel above the base layer, and having a non-transmissive area for blocking external light and a transmissive area for transmitting external light, a driving scan line connected to the pixel, and extending in a first direction, a sensing scan line connected to the pixel, and extending in the first direction, a horizontal voltage line connected to the pixel, and extending in the first direction, a data line connected to the pixel, and extending in a second direction crossing the first direction, a light-blocking pattern layer above the base layer, and including the data line, a gate pattern layer above the buffer layer, configured to cover the light-blocking pattern layer, and including two of the driving scan line, the sensing scan line, or the horizontal voltage line, and a data pattern layer above the inter insulating layer, configured to cover the gate pattern layer, and including a remaining one of the driving scan line, the sensing scan line, or the horizontal voltage line.

The horizontal voltage line may be between the driving scan line and the sensing scan line in plan view, wherein a separation distance between the driving scan line and the sensing scan line is greater than a width of the horizontal voltage line in the second direction.

1 The horizontal voltage line may be on a different layer than the driving scan line and the sensing scan line.

The gate pattern layer may include the driving scan line and the sensing scan line, wherein the data pattern layer includes the horizontal voltage line.

The horizontal voltage line may be between the driving scan line and the sensing scan line in plan view, wherein a separation distance between the driving scan line and the sensing scan line is less than a width of the horizontal voltage line in the second direction.

The display device may further include a first voltage line connected to the pixel, and extending in the second direction, and a second voltage line connected to the pixel, extending in the second direction, and spaced from the first voltage line in the first direction, wherein the horizontal voltage line is connected to the first voltage line or the second voltage line.

The pixel may include a first sub-pixel configured to output light of a first color, a second sub-pixel configured to output light of a second color, and a third sub-pixel configured to output light of a third color.

The display device may further include a first data line connected to the first sub-pixel, and extending in the second direction, a second data line connected to the second sub-pixel, and extending in the second direction, and a third data line connected to the third sub-pixel, and extending in the second direction, wherein the first data line, the second data line, and the third data line overlap the non-transmissive area.

The first data line, the second data line, and the third data line may be on a different layer than the driving scan line, the sensing scan line, and the horizontal voltage line.

The display device may further include a first voltage line connected to the pixel, and extending in the second direction, and a second voltage line connected to the pixel, extending in the second direction, and spaced from the first voltage line in 1 the first direction, wherein the first voltage line and the second voltage line are on a same layer as the first data line, the second data line, and the third data line.

The display device may further include a first connection line connecting the driving scan line to the first sub-pixel, the second sub-pixel, and the third sub-pixel, and a second connection line connecting the sensing scan line to the first sub-pixel, the second sub-pixel, and the third sub-pixel, wherein the first connection line and the second connection line are on a same layer as the driving scan line and the sensing scan line, and wherein the first connection line and the second connection line are on a different layer than the horizontal voltage line.

### BRIEF DESCRIPTION OF THE DRAWING

The above and other aspects of the present disclosure will become apparent by describing in detail embodiments thereof with reference to the accompanying drawings.

FIG. 1 is a perspective view of a display device according to one or more embodiments of the present disclosure.

FIG. 2 is a schematic sectional view of the display device according to one or more embodiments of the present disclosure.

FIG. 3 is a plan view illustrating a transmissive area and a non-transmissive area in a pixel according to one or more embodiments of the present disclosure.

FIG. 4 is a plan view illustrating a connection relationship between first to third sub-pixels and lines according to one or more embodiments of the present disclosure.

FIG. 5 is a circuit diagram illustrating the first to third sub-pixels according to one or more embodiments of the present disclosure.

FIG. 6 is a sectional view of a display panel according to one or more embodiments of the present disclosure.

1 FIG. 7 is a plan view illustrating a layout of the pixel according to one or more embodiments of the present disclosure.

FIG. 8A is an enlarged view of portion AA of FIG. 7.

FIG. 8B is a sectional view taken along the line I-l′ illustrated in FIG. 8A.

FIG. 8C is an enlarged view of portion AA of FIG. 7 according to one or more embodiments of the present disclosure.

FIG. 8D is a sectional view taken along the line II-II′ illustrated in FIG. 8C.

FIG. 9A is an enlarged view of portion AA of FIG. 7 according to one or more embodiments of the present disclosure.

FIG. 9B is a sectional view taken along the line III-III′ illustrated in FIG. 9A.

FIG. 9C is an enlarged view of portion AA of FIG. 7 according to one or more embodiments of the present disclosure.

FIG. 10A is an enlarged view of portion AA of FIG. 7 according to one or more embodiments of the present disclosure.

FIG. 10B is a sectional view taken along the line IV-IV′ illustrated in FIG. 10A.

FIGS. 11A to 11F are process views illustrating a manufacturing process of the display panel according to one or more embodiments of the present disclosure.

### DETAILED DESCRIPTION

Aspects of some embodiments of the present disclosure and methods of accomplishing the same may be understood more readily by reference to the detailed description of embodiments and the accompanying drawings. The described embodiments are provided as examples so that this disclosure will be thorough and complete, and will fully convey the aspects of the present disclosure to those skilled in the art. Accordingly, processes, elements, and techniques that are redundant, that are unrelated or irrelevant to the description of the embodiments, or that are not necessary to those having ordinary skill in the art for a complete understanding of the aspects of 1 the present disclosure may be omitted. Unless otherwise noted, like reference numerals, characters, or combinations thereof denote like elements throughout the attached drawings and the written description, and thus, repeated descriptions thereof may be omitted.

The described embodiments may have various modifications and may be embodied in different forms, and should not be construed as being limited to only the illustrated embodiments herein. The use of “can,” “may,” or “may not” in describing an embodiment corresponds to one or more embodiments of the present disclosure. A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

In the drawings, the relative sizes of elements, layers, and regions may be exaggerated for clarity and/or descriptive purposes. In other words, because the sizes and thicknesses of elements in the drawings are arbitrarily illustrated for convenience of description, the disclosure is not limited thereto. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result of, for example, manufacturing techniques and/or tolerances, are to be expected. Further, 1 specific structural or functional descriptions disclosed herein are merely illustrative for the purpose of describing embodiments according to the concept of the present disclosure. Thus, embodiments disclosed herein should not be construed as limited to the illustrated shapes of elements, layers, or regions, but are to include deviations in shapes that result from, for instance, manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place.

Spatially relative terms, such as “beneath,” “below,” “lower,” “lower side,” “under,” “above,” “upper,” “over,” “higher,” “upper side,” “side” (e.g., as in “sidewall”), and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below,” “beneath,” “or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, the phrase “in a plan view” means when an object portion is viewed from above, and the phrase “in a schematic cross-sectional view” means when a schematic cross-section taken by vertically cutting an object portion is viewed from the 1 side. The terms “overlap” or “overlapped” mean that a first object may be above or below or to a side of a second object, and vice versa. Additionally, the term “overlap” may include stack, face or facing, extending over, covering, or partly covering or any other suitable term as would be appreciated and understood by those of ordinary skill in the art. The expression “not overlap” may include meaning, such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

It will be understood that when an element, layer, region, or component is referred to as being “formed on,” “on,” “connected to,” or “(operatively or communicatively) coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In addition, this may collectively mean a direct or indirect coupling or connection and an integral or non-integral coupling or connection. For example, when a layer, region, or component is referred to as being “electrically connected” or “electrically coupled” to another layer, region, or component, it can be directly electrically connected or coupled to the other layer, region, and/or component or one or more intervening layers, regions, or components may be present. The one or more intervening components may include a switch, a resistor, a capacitor, and/or the like. In describing embodiments, an expression of connection indicates electrical connection unless explicitly described to be direct connection, and “directly connected/directly coupled,” or “directly on,” refers to one component directly 1 connecting or coupling another component, or being on another component, without an intermediate component.

In addition, in the present specification, when a portion of a layer, a film, an area, a plate, or the like is formed on another portion, a forming direction is not limited to an upper direction but includes forming the portion on a side surface or in a lower direction. On the contrary, when a portion of a layer, a film, an area, a plate, or the like is formed “under” another portion, this includes not only a case where the portion is “directly beneath” another portion but also a case where there is further another portion between the portion and another portion. Meanwhile, other expressions describing relationships between components, such as “between,” “immediately between” or “adjacent to” and “directly adjacent to,” may be construed similarly. It will be understood that when an element or layer is referred to as being “between” two elements or layers, it can be the only element or layer between the two elements or layers, or one or more intervening elements or layers may also be present.

For the purposes of this disclosure, expressions such as “at least one of,” or “any one of,” or “one or more of” when preceding a list of elements, modify the entire list of elements and do not modify the individual elements of the list. For example, “at least one of X, Y, and Z,” “at least one of X, Y, or Z,” “at least one selected from the group consisting of X, Y, and Z,” and “at least one selected from the group consisting of X, Y, or Z” may be construed as X only, Y only, Z only, any combination of two or more of X, Y, and Z, such as, for instance, XYZ, XYY, YZ, and ZZ, or any variation thereof. Similarly, the expressions “at least one of A and B” and “at least one of A or B” may include A, B, or A and B. As used herein, “or” generally means “and/or,” and the term “and/or” includes any and all combinations of one or more of the associated listed items. For example, the expression “A and/or B” may include A, B, or A and B. Similarly, expressions such as “at least one of,” “a plurality of,” “one of,” and other prepositional phrases, when preceding a list of elements, modify the entire list of elements and do not modify the individual elements of the list. When “C to D” is stated, it means C or more and D or less, unless otherwise specified.

It will be understood that, although the terms “first,” “second,” “third,” etc., may be used herein to describe various elements, components, regions, layers and/or sections, these elements, components, regions, layers and/or sections should not be limited by these terms. These terms do not correspond to a particular order, position, or superiority, and are used only used to distinguish one element, member, component, region, area, layer, section, or portion from another element, member, component, region, area, layer, section, or portion. Thus, a first element, component, region, layer or section described below could be termed a second element, component, region, layer or section, without departing from the spirit and scope of the present disclosure. The description of an element as a “first” element may not require or imply the presence of a second element or other elements. The terms “first,” “second,” etc. may also be used herein to differentiate different categories or sets of elements. For conciseness, the terms “first,” “second,” etc. may represent “first-category (or first-set),” “second-category (or second-set),” etc., respectively.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing embodiments only and is not intended to be limiting of the present disclosure. As used herein, the singular forms “a” and “an” are intended to include the plural forms as well, while the plural forms are also intended to include the singular forms, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

When one or more embodiments may be implemented differently, a specific process order may be performed differently from the described order. For example, two consecutively described processes may be performed substantially at the same time or performed in an order opposite to the described order.

As used herein, the terms “substantially,” “about,” “approximately,” and similar terms are used as terms of approximation and not as terms of degree, and are intended to account for the inherent deviations in measured or calculated values that would be recognized by those of ordinary skill in the art. For example, “substantially” may include a range of +/−5% of a corresponding value. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value. Further, the use of “may” when describing embodiments of the present disclosure refers to “one or more embodiments of the present disclosure.”

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

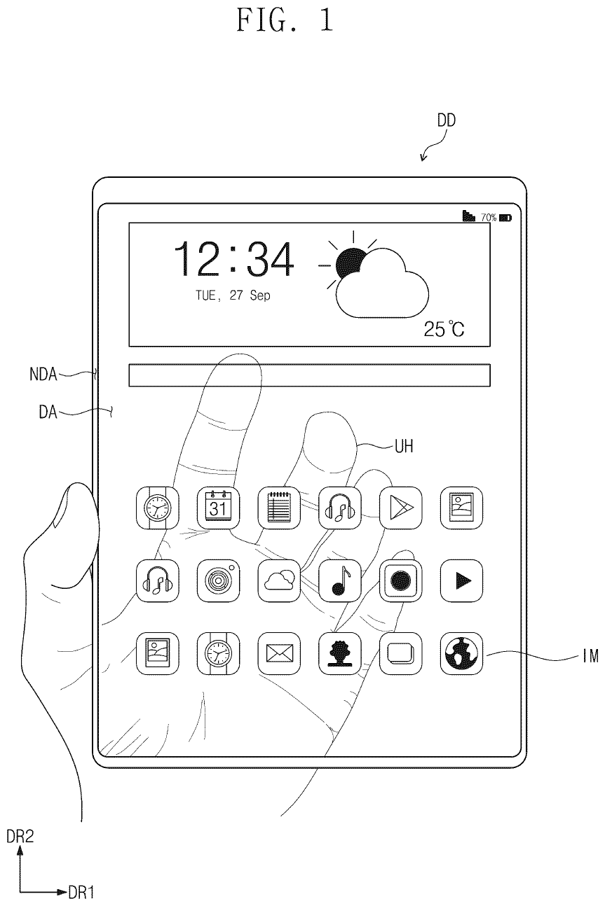

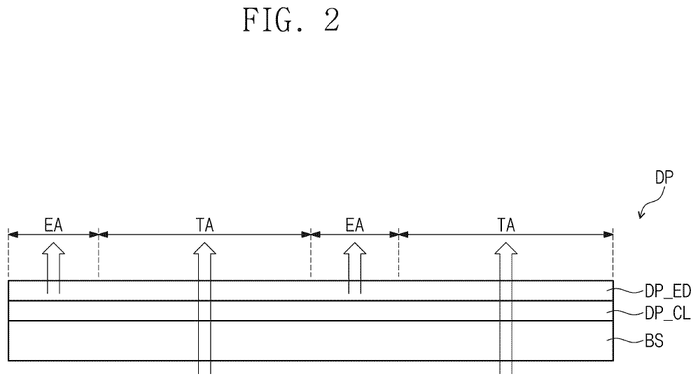

FIG. 1 is a perspective view of a display device according to one or more embodiments of the present disclosure, and FIG. 2 is a schematic sectional view of the display device according to one or more embodiments of the present disclosure.

Referring to FIG. 1, the display device DD according to one or more embodiments of the present disclosure may be used not only for large electronic devices, such as a television, a monitor, and a billboard, but also for small- and medium-sized electronic devices, such as a personal computer, a notebook computer, a personal digital terminal, a car navigation unit, a game machine, a portable electronic device, and a camera. However, these devices are merely illustrative, and the display device DD may be employed for other electronic devices without departing from the spirit and scope of the present disclosure.

The display device DD may be a transparent display device. That is, the display device DD may have a high transmittance sufficient to allow an object or background located behind to be visible. FIG. 1 illustrates an example that a user's hand UH located behind the display device DD is visually recognized.

The display device DD may have a display area DA and a non-display area NDA defined therein. The display area DA is an area where an image IM is displayed, and the non-display area NDA is an area that is adjacent to the display area DA and where the image IM is not displayed. Accordingly, the user may visually recognize the image IM displayed on the display area DA. An object or an image that is located behind the display device DD may be visible in the display area DA.

A bezel area of the display device DD may be defined by the non-display area NDA. The object or the image that is located behind the display device DD isn't visible in the non-display area NDA. The non-display area NDA may surround the display area DA. However, this is illustrative, and the non-display area NDA may be adjacent to only a portion of the periphery of the display area DA. Alternatively, the non-display area NDA may be omitted. However, the present disclosure is not limited to any one of the embodiments.

Referring to FIGS. 1 and 2, the display device DD may include a display panel DP. The display panel DP may be an emissive display panel. For example, the display panel DP may be an organic light-emitting display panel, an inorganic light-emitting display panel, or a quantum-dot light-emitting display panel. An emissive layer of the organic light-emitting display panel may include an organic luminescent material. An emissive layer of the inorganic light-emitting display panel may include an inorganic luminescent material. An emissive layer of the quantum-dot light-emitting display panel may include quantum dots and quantum rods.

The display panel DP includes a base layer BS, a circuit layer DP_CL, and an element layer DP_ED. The display panel DP according to the present disclosure may be a flexible display panel. However, the present disclosure is not limited thereto. For example, the display panel DP may be a foldable display panel that is folded about a folding axis, or may be a rigid display panel.

The base layer BS may include a synthetic resin layer. The synthetic resin layer may be a polyimide-based resin layer, and the material thereof is not particularly limited. In addition, the base layer BS may include a glass substrate, a metal substrate, or an organic/inorganic composite substrate.

The circuit layer DP_CL is located on the base layer BS. The circuit layer DP_CL is located between the base layer BS and the element layer DP_ED. The circuit layer DP_CL includes at least one insulating layer and a circuit element. Hereinafter, the insulating layer included in the circuit layer DP_CL is referred to as an intermediate insulating layer. The intermediate insulating layer includes at least one intermediate inorganic film and at least one intermediate organic film. The circuit element may include a pixel-driving circuit included in each of a plurality of pixels for displaying an image.

The element layer DP_ED may include a light-emitting element included in each of the pixels. In one or more embodiments of the present disclosure, the light-emitting element may be an organic light-emitting diode. The light-emitting element is provided to correspond to an emissive area EA. Accordingly, the display panel DP may display an image through a plurality of emissive areas EA. In addition, the display panel DP may transmit external light through a transmissive area TA. Accordingly, the display panel DP may display an image using light generated from the emissive area EA, and may allow an object or background located behind to be visible through the transmissive area TA.

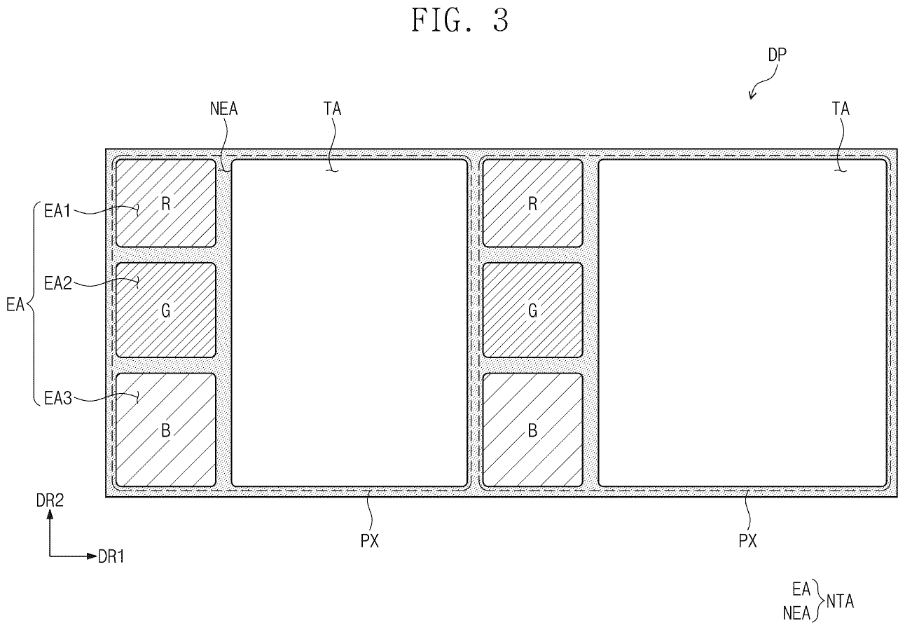

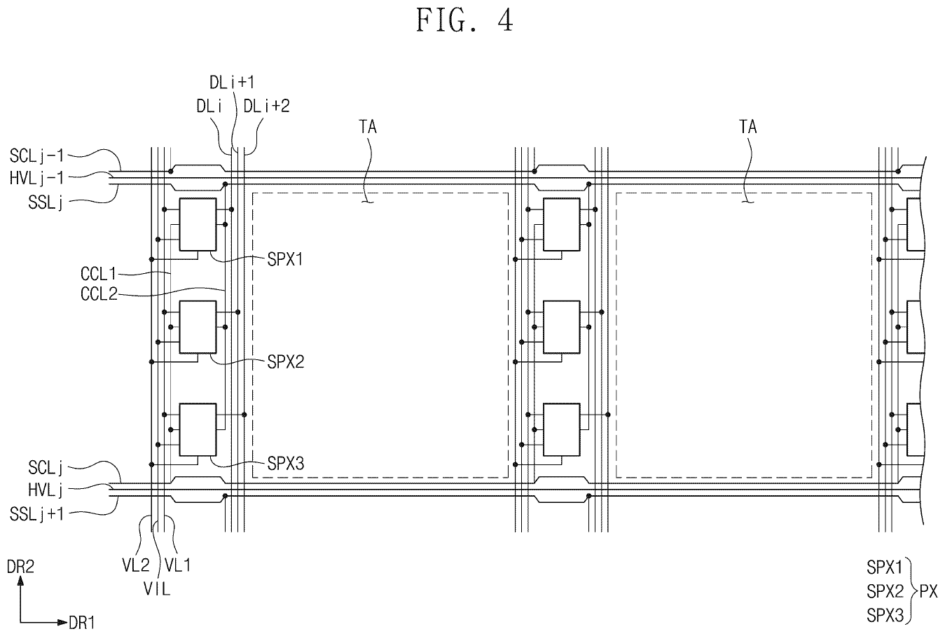

A non-transmissive area NTA (refer to FIG. 3) in which various elements and lines are provided, and therefore the transmittance of external light is extremely low, or the external light is hardly transmitted may be defined in the display panel DP. The emissive area EA may be included in the non-transmissive area NTA. Because various elements and lines are not provided in the transmissive area TA, the transmissive area TA may have a relatively high external light transmittance. As the area occupied by the transmissive area TA in the display panel DP is increased, the external light transmittance may be increased.

The display panel DP may further include an encapsulation layer that seals the element layer DP_ED. The encapsulation layer may include at least one organic film and at least one inorganic film. The inorganic film may include an inorganic material, and may protect the element layer DP_ED from moisture/oxygen. The inorganic film may include a silicon nitride layer, a silicon oxy nitride layer, a silicon oxide layer, a titanium oxide layer, or an aluminum oxide layer, but is not particularly limited thereto. The organic film may include an organic material, and may protect the element layer DP_ED from foreign matter such as dust particles.

FIG. 3 is a plan view illustrating a transmissive area and a non-transmissive area in a pixel according to one or more embodiments of the present disclosure.

Referring to FIG. 3, the display panel DP may include a plurality of pixels PX. The plurality of pixels PX may have the same structure. Each of the plurality of pixels PX may include a non-transmissive area NTA and a transmissive area TA. The non-transmissive area NTA may be formed to surround the transmissive area TA (e.g., in 1 plan view). In one or more embodiments of the present disclosure, the non-transmissive area NTA may include an emissive area EA and a non-emissive area NEA. The non-emissive area NEA may surround the emissive area EA and the transmissive area TA (e.g., in plan view).

Among the plurality of pixels PX, two adjacent pixels PX are illustrated in FIG. 3. Each of the pixels PX may include a plurality of sub-pixels. The emissive area EA includes a plurality of emissive areas EA1, EA2, and EA3 that correspond to the plurality of sub-pixels, respectively.

In one or more embodiments of the present disclosure, each pixel PX may include a first sub-pixel that outputs first color light R (or, red light), a second sub-pixel that outputs second color light G (or, green light), and a third sub-pixel that outputs third color light B (or, blue light). A first emissive area EA1 is defined in the first sub-pixel, a second emissive area EA2 is defined in the second sub-pixel, and a third emissive area EA3 is defined in the third sub-pixel. At least one of the first to third sub-pixels may have a different size from the remaining sub-pixels. For example, the third sub-pixel may have a larger size than the first and second sub-pixels. In this case, the third emissive area EA3 corresponding to the third sub-pixel may have a larger size than the first and second emissive areas EA1 and EA2 that correspond to the first and second sub-pixels, respectively. Alternatively, the first to third sub-pixels may have the same size.

The transmissive area TA may have a size that is greater than the sum of the sizes of the first to third sub-pixels. However, without being limited thereto, the size of the transmissive area TA may vary depending on a desired transmittance of the display device DD.

Although FIG. 3 illustrates the structure in which each pixel PX has one transmissive area TA, the present disclosure is not limited thereto. That is, each pixel PX may have a plurality of transmissive areas TA. For example, each pixel PX may 1 include three transmissive areas that are adjacent to the first to third sub-pixels, respectively.

Although FIG. 3 illustrates the structure in which each of the emissive areas EA1 to EA3 has a quadrangular shape defined in the first and second directions DR1 and DR2, the shapes of the emissive areas EA1 to EA3 are not limited thereto. For example, each of the emissive areas EA1 to EA3 may have a rhombic shape.

Although the transmissive area TA is also illustrated as having a quadrangular shape defined in the first and second directions DR1 and DR2, the shape of the transmissive area TA may vary depending on the shapes of the emissive areas EA1 to EA3.

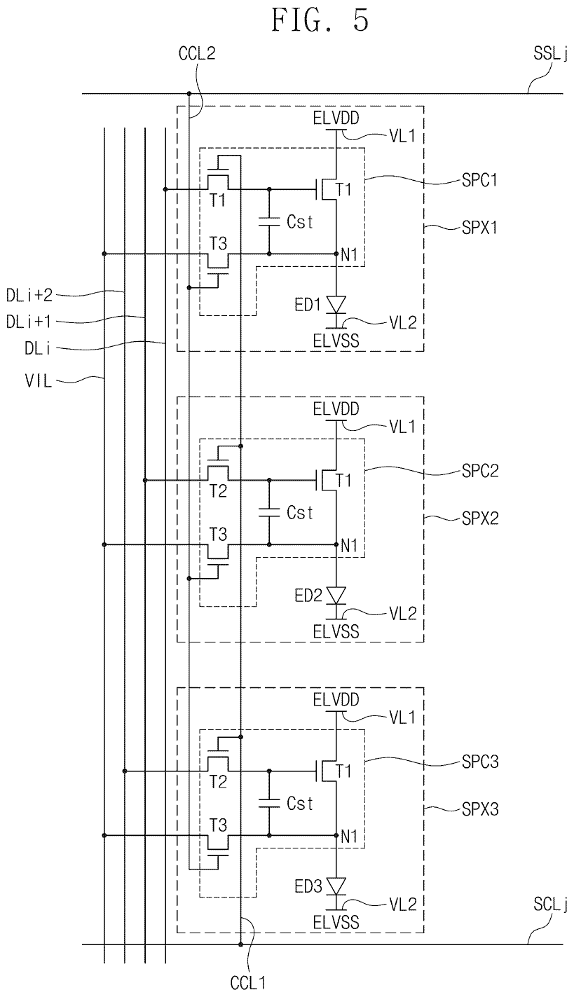

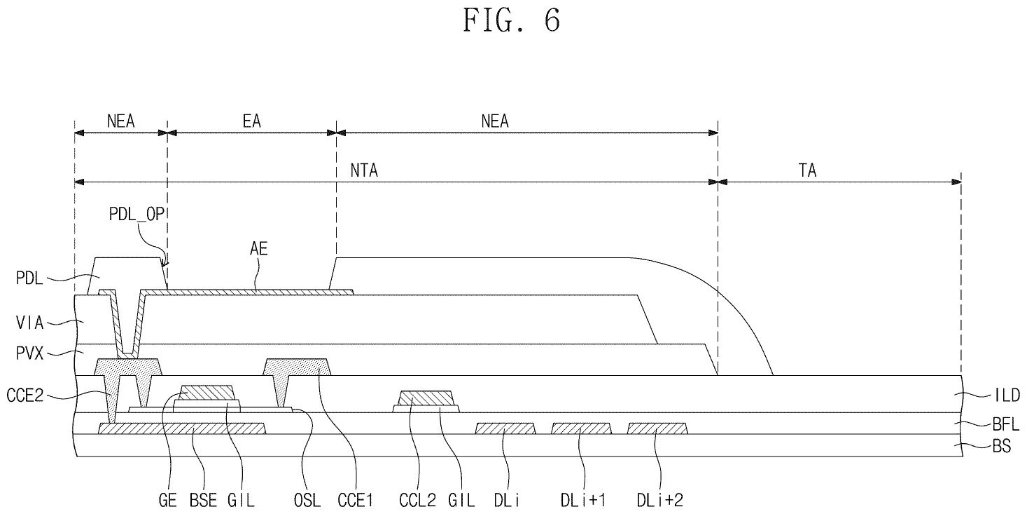

FIG. 4 is a plan view illustrating a connection relationship between the first to third sub-pixels and lines according to one or more embodiments of the present disclosure. FIG. 5 is a circuit diagram illustrating the first to third sub-pixels according to one or more embodiments of the present disclosure.

Referring to FIGS. 4 and 5, each pixel PX includes the first to third sub-pixels SPX1, SPX2, and SPX3. The first sub-pixel SPX1 includes a first pixel circuit SPC1 and a first light-emitting element ED1, the second sub-pixel SPX2 includes a second pixel circuit SPC2 and a second light-emitting element ED2, and the third sub-pixel SPX3 includes a third pixel circuit SPC3 and a third light-emitting element ED3. In one or more embodiments of the present disclosure, the first to third pixel circuits SPC1 to SPC3 may have the same circuit configuration.

Each pixel PX may be connected to two scan lines (hereinafter, referred to as a j^{th} driving scan line SCLj and a j^{th} sensing scan line SSLj), three data lines (hereinafter, referred to as an i^{th} data line DLi, an (i+1)^{th} data line DLi+1, and an (i+2)^{th} data line DLi+2), first and second driving voltage lines VL1 and VL2, and an initialization voltage line VIL. Here, j and i are integers of 1 or more.

The j^{th} driving scan line SCLj and the j^{th} sensing scan line SSLj may extend in the first direction DR1, and the i^{th} data line DLi, the (i+1)^{th} data line DLi+1, and the (i+2)^{th} data line DLi+2 may extend in the second direction DR2, and may cross the j^{th} driving scan line SCLj and the j^{th} sensing scan line SSLj. The first and second driving voltage lines VL1 and VL2 and the initialization voltage line VIL may extend in the second direction DR2, and may be spaced apart from the i^{th} data line DLi, the (i+1)^{th} data line DLi+1, and the (i+2)^{th} data line DLi+2 in the first direction DR1. The first and second driving voltage lines VL1 and VL2 and the initialization voltage line VIL may cross the j^{th} driving scan line SCLj and the j^{th} sensing scan line SSLj.

The j^{th} driving scan line SCLj and the j^{th} sensing scan line SSLj may be located on the lower and upper sides of the pixel PX, respectively, when viewed from above the plane. The j^{th} driving scan line SCLj is commonly connected to the first to third pixel circuits SPC1, SPC2, and SPC3 through a first connection line CCL1, and the j^{th} sensing scan line SSLj is commonly connected to the first to third pixel circuits SPC1, SPC2, and SPC3 through a second connection line CCL2.

The i^{th} data line DLi, the (i+1)^{th} data line DLi+1, and the (i+2)^{th} data line DLi+2 may be connected to the first to third pixel circuits SPC1, SPC2, and SPC3, respectively. That is, the i^{th} data line DLi is connected to the first pixel circuit SPC1, the (i+1)^{th} data line DLi+1 is connected to the second pixel circuit SPC2, and the (i+2)^{th} data line DLi+2 is connected to the third pixel circuit SPC3. The i^{th} data line DLi, the (i+1)^{th} data line DLi+1, and the (i+2)^{th} data line DLi+2 may be referred to as a first data line, a second data line, and a third data line, respectively.

A (j−1)^{th} horizontal voltage line HVLj−1 is located between the (j−1)^{th} driving scan line SCLj−1 and the j^{th} sensing scan line SSLj, and a j^{th} horizontal voltage line HVLj is located between the j^{th} driving scan line SCLj and the (j+1)^{th} sensing scan line SSLj+1. Each of the (j−1)^{th} horizontal voltage line HVLj−1 and the j^{th} horizontal voltage line HVLj extends in the first direction DR1. In one or more embodiments of the present disclosure, the (j−1)^{th} horizontal voltage line HVLj−1 may be connected with the first driving voltage line VL1, and the j^{th} horizontal voltage line HVLj may be connected with the second driving voltage line VL2. Accordingly, the (j−1)^{th} horizontal voltage line HVLj−1 may function as the first driving voltage line VL1, and the j^{th} horizontal voltage line HVLj may function as the second driving voltage line VL2.

Each of the first to third pixel circuits SPC1 to SPC3 may include three transistors and one capacitor. Each of the first to third pixel circuits SPC1 to SPC3 includes first to third transistors T1, T2, and T3 and a capacitor Cst. At least one of the first to third transistors T1, T2, and T3 may be an oxide transistor having an oxide semiconductor layer. Each of the first to third transistors T1, T2, and T3 may be an N-type transistor. However, the present disclosure is not limited thereto. For example, each of the first to third transistors T1, T2, and T3 may be a P-type transistor. Alternatively, one or more of the first to third transistors T1, T2, or T3 may be an N-type transistor, and one or more others may be P-type transistors. In addition, at least one of the first to third transistors T1, T2, or T3 may be a transistor having a low-temperature polycrystalline silicon (LTPS) semiconductor layer.

The first transistor T1 is connected between the first driving voltage line VL1 that receives a first driving voltage ELVDD and one light-emitting element (hereinafter, referred to as the corresponding light-emitting element) among the first to third light-emitting elements ED1 and ED3. The first transistor T1 includes a first electrode connected with the first driving voltage line VL1, a second electrode electrically connected with an anode of the corresponding light-emitting element, and a third electrode connected with one end of the capacitor Cst. Here, a contact point at which the anode of the corresponding light-emitting element and the second electrode of the first transistor T1 are connected may be referred to as a first node N1. The expression “a transistor is connected to a signal line,” as used herein, means that one of first to third electrodes of the transistor has a one-body shape with, or is formed integrally with, the signal line, or is connected with the signal line through a connection electrode. In addition, the expression “one transistor is electrically connected with another transistor,” as used herein, means that one of first to third electrodes of the one transistor has a one-body shape with, or is integral with, one of first to third electrodes 1 of the other transistor, or is connected with the one of the first to third electrodes of the other transistor through a connection electrode.

The first transistor T1 may receive a data voltage that at least one data line (hereinafter, referred to as the corresponding data line) among the i^{th}, (i+1)^{th}, and (i+2)^{th} data lines DLi, DLi+1, and DLi+2 transfers depending on a switching operation of the second transistor T2, and may supply a driving current to the corresponding light-emitting element.

The second transistor T2 is connected between the corresponding data line and the third electrode of the first transistor T1. The second transistor T2 includes a first electrode connected with the corresponding data line, a second electrode connected with the third electrode of the first transistor T1, and a third electrode connected with the j^{th} driving scan line SCLj. Here, a contact point at which the second electrode of the second transistor T2 and the third electrode of the first transistor T1 are connected may be referred to as a second node N2. The second transistor T2 may be turned on depending on the j^{th} driving scan signal transferred through the j^{th} driving scan line SCLj, and may transfer the data voltage transferred from the corresponding data line to the third electrode of the first transistor T1.

The third transistor T3 is connected between the second electrode of the first transistor T1 and the initialization voltage line VIL. The third transistor T3 includes a first electrode connected to the first node N1, a second electrode connected with the initialization voltage line VIL, and a third electrode connected with the j^{th} sensing scan line SSLj. The third transistor T3 may be turned on depending on the j^{th} sensing scan signal transferred through the j^{th} sensing scan line SSLj, and may electrically connect the initialization voltage line VIL and the first node N1.

The one end of the capacitor Cst is connected to the second node N2, and the opposite end of the capacitor Cst is connected with the first node N1. A cathode of the corresponding light-emitting element may be connected with the second driving voltage line VL2 that transfers a second driving voltage ELVSS. The second driving voltage ELVSS may have a voltage level that is lower than the first driving voltage ELVDD.

The configuration of the first to third pixel circuits SPC1 to SPC3 according to the present disclosure is not limited to the embodiments corresponding to FIG. 4.

The first to third pixel circuits SPC1 to SPC3 illustrated in FIG. 4 are merely illustrative, and various changes and modifications may be made to the configuration of the first to third pixel circuits SPC1 to SPC3. For example, the third transistor T3 may be omitted from each of the first to third pixel circuits SPC1 to SPC3.

Each of the first to third light-emitting elements ED1 to ED3 may include the anode connected to the second electrode of the first transistor T1 (or, the first node N1) and the cathode that receives the second driving voltage ELVSS. Each of the first to third light-emitting elements ED1 to ED3 may generate light corresponding to the amount of current supplied from the first transistor T1.

The j^{th} driving scan line SCLj and the j^{th} sensing scan line SSLj are located in the non-transmissive area NTA, and do not overlap the transmissive area TA. The i^{th} data line DLi, the (i+1)^{th} data line DLi+1, and the (i+2)^{th} data line DLi+2 are located in the non-transmissive area NTA, and do not overlap the transmissive area TA.

As described above, the signal lines SSLj, SCLj, DLi, DLi+1, and DLi+2 are located so as not to pass through and overlap the transmissive area TA. Accordingly, there may be reduced or prevented the likelihood of a phenomenon in which external light incident to the transmissive area TA is reflected by the signal lines SSLj, SCLj, DLi, DLi+1, and DLi+2, such that the transmittance of the display panel DP is deteriorated. Thus, the user may clearly recognize an object located behind the display panel DP or an image.

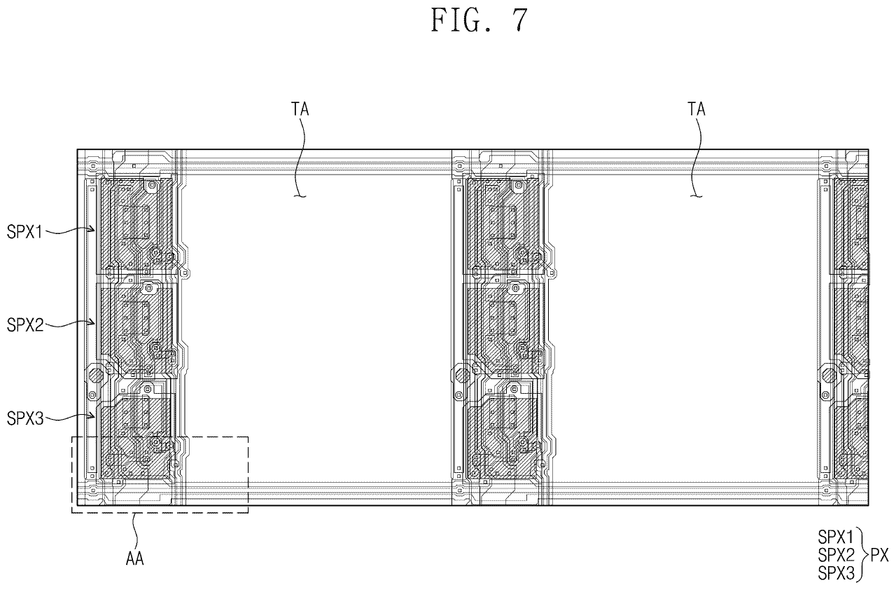

FIG. 6 is a sectional view of the display panel according to one or more embodiments of the present disclosure.

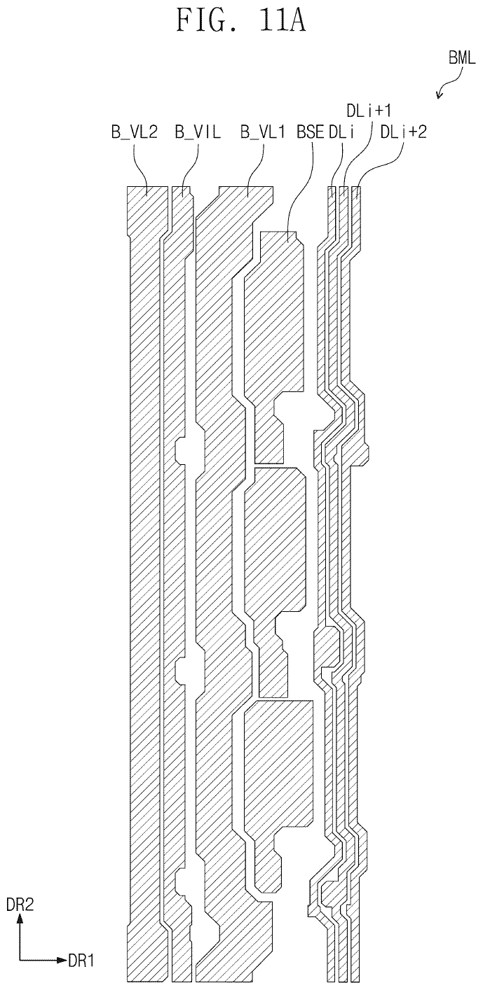

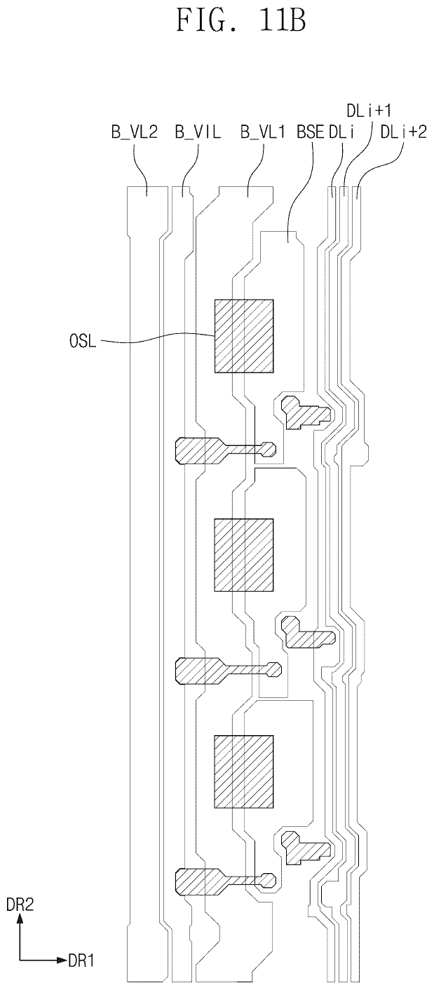

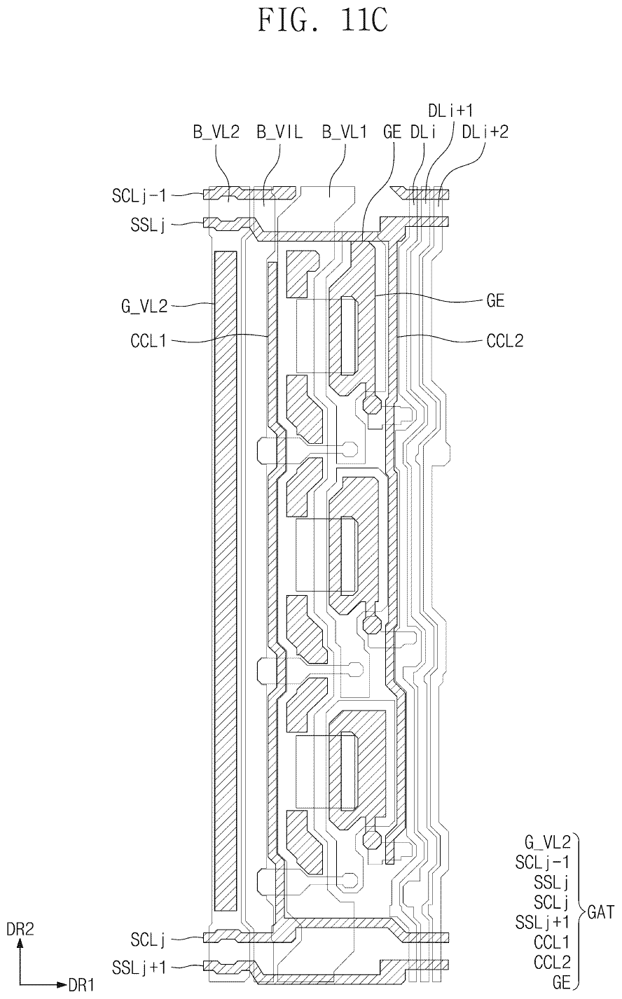

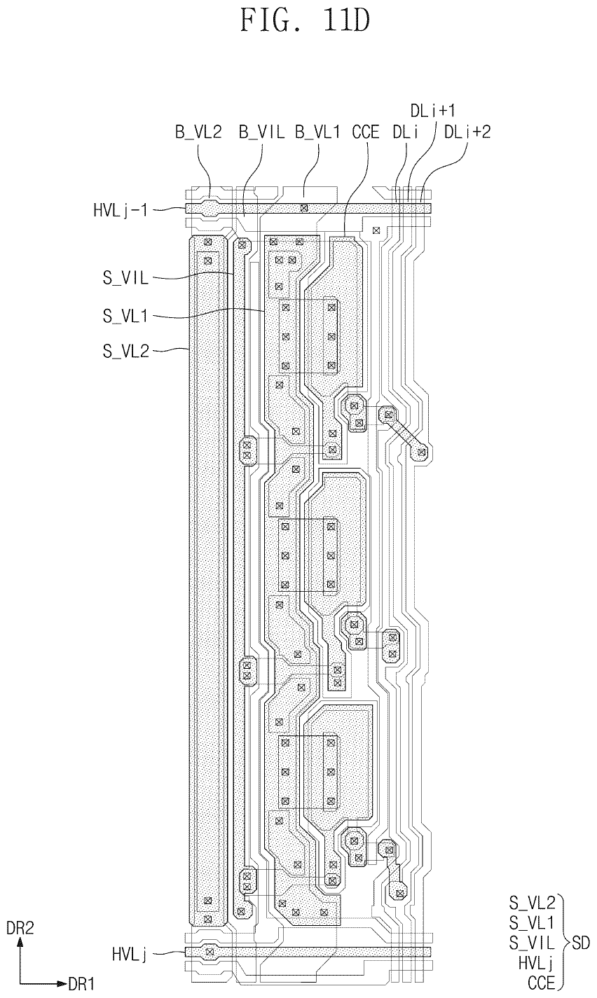

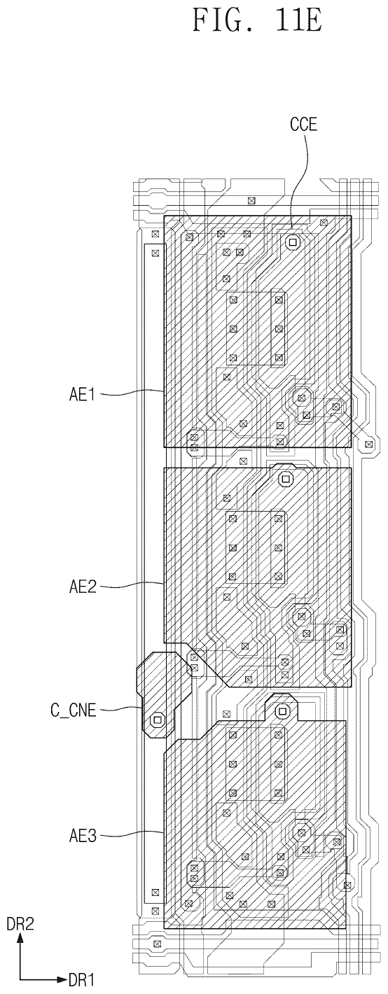

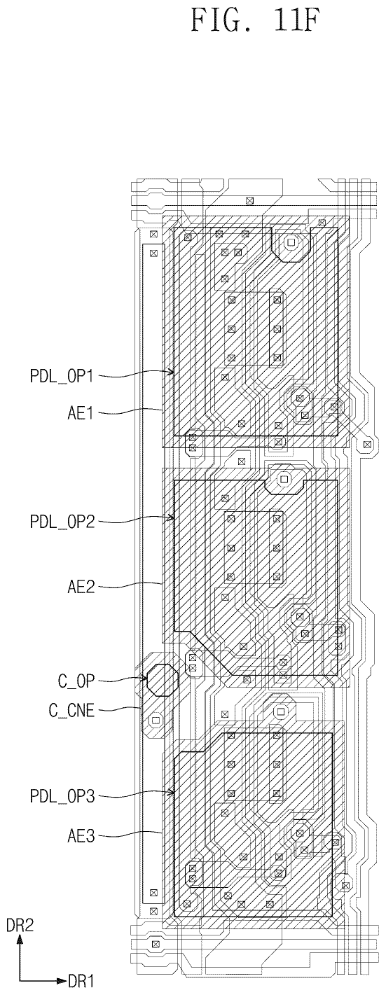

Referring to FIGS. 4 and 6, a light-blocking pattern layer BML (refer to FIG. 11A) is located on the upper surface of the base layer BS. In one or more embodiments of the present disclosure, the light-blocking pattern layer BML may include a shielding electrode BSE, data lines (that is, the i^{th} data line DLi, the (i+1)^{th} data line DLi+1, and the (i+2)^{th} data line DLi+2), the first and second driving voltage lines VL1 and VL2, and the initialization voltage line VIL. The shielding electrode BSE may be located in the form of an island. In addition, the shielding electrode BSE may be electrically connected with one of the first driving voltage line VL1, the second driving voltage line VL2, and the initialization voltage line VIL.

A buffer layer BFL is located on the base layer BS to cover the light-blocking pattern layer BML (as used herein, “located on” may mean “above”). The buffer layer BFL may include a silicon oxide layer or a silicon nitride layer. Alternatively, the buffer layer BFL may have a structure in which silicon oxide layers and silicon nitride layers are alternately stacked one above another.

A semiconductor pattern OSL is located on the buffer layer BFL. The semiconductor pattern OSL may correspond to one of a plurality of patterns of a semiconductor layer located on the buffer layer BFL. The semiconductor pattern OSL may overlap the shielding electrode BSE when viewed from above the plane. Accordingly, the shielding electrode BSE may block light, such that the light is not provided toward the semiconductor pattern OSL.

The semiconductor pattern OSL may include metal oxide. A metal oxide semiconductor may include a crystalline or amorphous oxide semiconductor. For example, the oxide semiconductor may include metal oxide of zinc (Zn), indium (In), gallium (Ga), tin (Sn), or titanium (Ti). Alternatively, the oxide semiconductor may include a mixture of metal such as zinc (Zn), indium (In), gallium (Ga), tin (Sn), or titanium (Ti) or oxide thereof. The oxide semiconductor may include indium-tin oxide (ITO), indium-gallium-zinc oxide (IGZO), zinc oxide (ZnO), indium-zinc oxide (IZO), zinc-indium oxide (ZIO), indium oxide (InO), titanium oxide (TiO), indium-zinc-tin oxide (IZTO), or zinc-tin oxide (ZTO).

1 The semiconductor pattern OSL may include a plurality of areas distinguished depending on whether the metal oxide included in the semiconductor pattern OSL is reduced or not. An area where the metal oxide is reduced (hereinafter, referred to as the reduced area) has a higher conductivity than an area where the metal oxide is not reduced (hereinafter, referred to as the non-reduced area). The reduced area substantially serves as a source/drain of a transistor or a signal line. The non-reduced area substantially corresponds to a semiconductor area (or, a channel area) of the transistor. In other words, one portion of the semiconductor pattern may be the channel area of the transistor, and another portion of the semiconductor pattern may be the source area or the drain area of the transistor.

Gate-insulating patterns GIL are located on the semiconductor pattern OSL or the buffer layer BFL. A part of the gate-insulating patterns GIL may overlap the channel area. The gate-insulating patterns GIL need not be entirely formed on the base layer BS, but may be formed to overlap only a corresponding conductive pattern layer (e.g., a gate pattern layer GAT (refer to FIG. 11C)) that will be described below. However, the present disclosure is not limited thereto, and in one or more embodiments of the present disclosure, the gate-insulating patterns GIL may entirely overlap the base layer BS.

The gate pattern layer GAT (refer to FIG. 11C) may be located on the gate-insulating patterns GIL. The gate pattern layer GAT may include the third electrode (or, the gate) GE of each of the first to third transistors T1 to T3 (refer to FIG. 5) and the first and second connection lines CCL1 and CCL2. In one or more embodiments of the present disclosure, the gate pattern layer GAT may further include the j^{th} driving scan line SCLj and the j^{th} sensing scan line SSLj.

An inter insulating layer ILD is located on the buffer layer BFL to cover the gate pattern layer GAT. A data pattern layer SD (refer to FIG. 11D) may be located on the inter insulating layer ILD. The data pattern layer SD may further include first and second connection electrodes CCE1 and CCE2, the (j−1)^{th} horizontal voltage line HVLj−1, and the j^{th} horizontal voltage line HVLj. The first and second connection electrodes CCE1 and CCE2 may be connected to the source area and the drain area of the semiconductor pattern OSL through contact holes penetrating the inter insulating layer ILD.

A protective layer PVX is located on the inter insulating layer ILD to cover the data pattern layer SD. A via layer VIA may be located on the protective layer PVX. The anode AE of each of the light-emitting elements ED1, ED2, and ED3 may be located on the via layer VIA. The anode AE may be connected to the second connection electrode CCE2 through a contact hole penetrating the via layer VIA and the protective layer PVX. Here, the second connection electrode CCE2 may be a connection electrode connected to the drain area of the first transistor T1.

A pixel-defining layer PDL may be located on the via layer VIA, and may cover a portion of the anode AE. An opening PDL_OP is defined in the pixel-defining layer PDL. The opening PDL_OP of the pixel-defining layer PDL exposes at least a portion of the anode AE.

An emissive layer may be located on the anode AE. The emissive layer may be located in an area corresponding to the opening PDL_OP. That is, the emissive layer may be separately formed for each of the sub-pixels. When the emissive layer is separately formed for each of the pixels, the emissive layers may each emit at least one of blue light, red light, or green light. However, without being limited thereto, the emissive layers may be connected together to have an integral/one-body shape, and may be commonly provided for the pixels. In this case, the emissive layer provided in a one-body shape may provide blue light or white light.

The cathode may be located on the emissive layer. The cathode may have a one-body shape, and may be commonly located for the pixels.

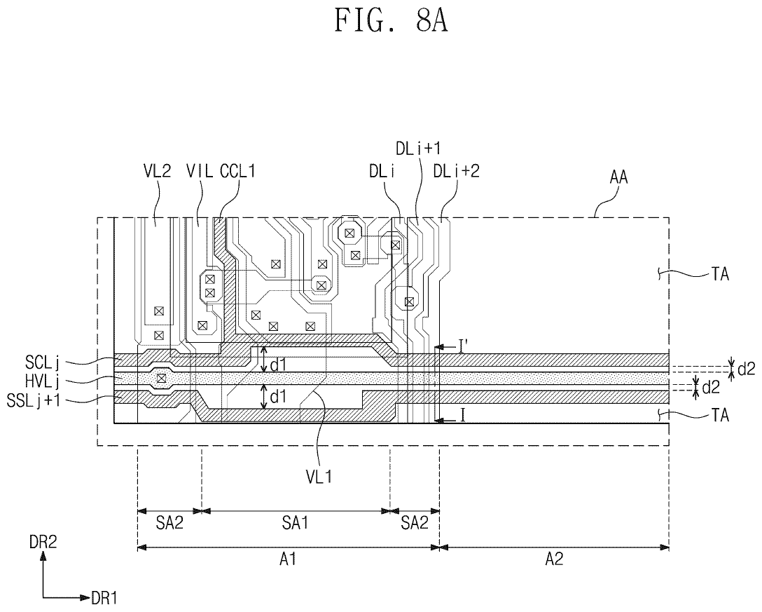

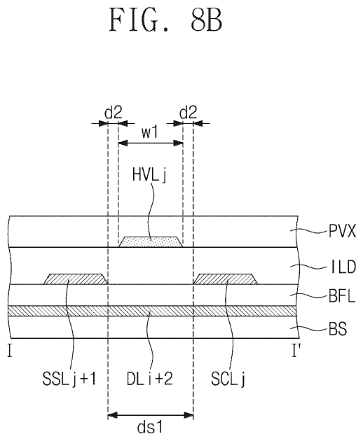

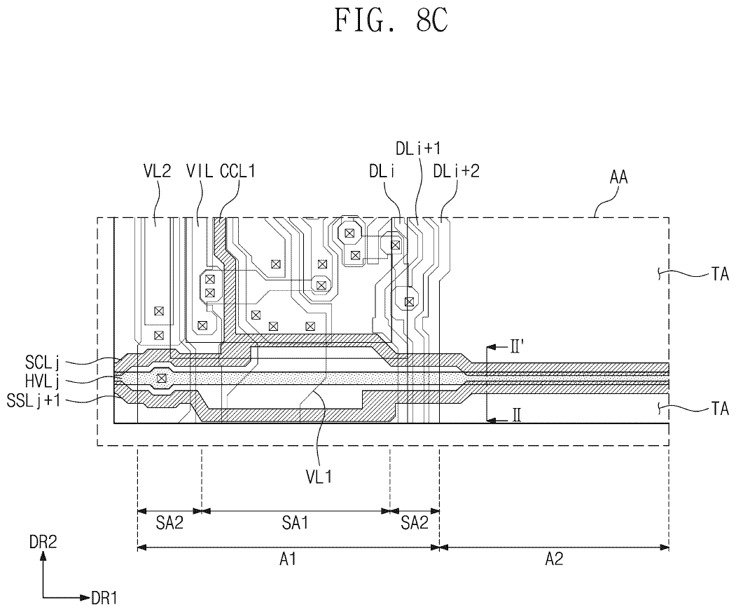

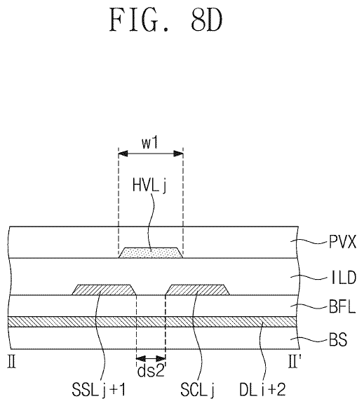

FIG. 7 is a plan view illustrating a layout of the pixel according to one or more embodiments of the present disclosure. FIG. 8A is an enlarged view of portion AA of FIG. 7. FIG. 8B is a sectional view taken along the line I-l′ illustrated in FIG. 8A.

1 Referring to FIGS. 4, 6, 7, and 8A, each of the plurality of pixels PX may include the non-transmissive area NTA and the transmissive area TA. The non-transmissive area NTA may be formed to surround the transmissive area TA. In one or more embodiments of the present disclosure, the non-transmissive area NTA may include the emissive area EA and the non-emissive area NEA. The non-emissive area NEA may surround the emissive area EA and the transmissive area TA (e.g., in plan view). In one or more embodiments of the present disclosure, the non-emissive area NEA may include a first non-emissive area (or, a first area) A1 and a second non-emissive area (or, a second area) A2. The first non-emissive area A1 is an area located between two emissive areas EA adjacent to each other in the second direction DR2, and the second non-emissive area A2 is an area located between two transmissive areas TA adjacent to each other in the second direction DR2.

In the first non-emissive area A1, the (j−1)^{th} driving scan line SCLj−1, the j^{th} sensing scan line SSLj, and the (j−1)^{th} horizontal voltage line HVLj−1 are spaced apart from each other at a first interval d1 in the second direction DR2. In the second non-emissive area A2, the (j−1)^{th} driving scan line SCLj−1, the j^{th} sensing scan line SSLj, and the (j−1)^{th} horizontal voltage line HVLj−1 are spaced apart from each other at a second interval d2 in the second direction DR2. Here, the second interval d2 is smaller than the first interval d1.

Similarly, in the first non-emissive area A1, the j^{th} driving scan line SCLj, the (j+1)^{th} sensing scan line SSLj+1, and the j^{th} horizontal voltage line HVLj are spaced apart from each other at the first interval d1 in the second direction DR2. In the second non-emissive area A2, the j^{th} driving scan line SCLj, the (j+1)^{th} sensing scan line SSLj+1, and the j^{th} horizontal voltage line HVLj are spaced apart from each other at the second interval d2 in the second direction DR2. Here, the second interval d2 is smaller than the first interval d1.

The first non-emissive area A1 may include a first sub-area SA1 and a second sub-area SA2. The first sub-area SA1 is an area where the j^{th} driving scan line 1 SCLj, the (j+1)^{th} sensing scan line SSLj+1, and the j^{th} horizontal voltage line HVLj are spaced apart from each other at the first interval d1, and the second sub-area SA2 is an area where the j^{th} driving scan line SCLj, the (j+1)^{th} sensing scan line SSLj+1, and the j^{th} horizontal voltage line HVLj are spaced apart from each other at the second interval d2. In one or more embodiments of the present disclosure, the second sub-area SA2 may be located between the first sub-area SA1 and the second non-emissive area A2.

As illustrated in FIG. 8B, the j^{th} driving scan line SCLj and the (j+1)^{th} sensing scan line SSLj+1 are located on the buffer layer BFL, and the j^{th} horizontal voltage line HVLj is located on the inter insulating layer ILD. However, the present disclosure is not limited thereto. The j^{th} horizontal voltage line HVLj may be located on the buffer layer BFL, and the j^{th} driving scan line SCLj and the (j+1)^{th} sensing scan line SSLj+1 may be located on the inter insulating layer ILD.

The j^{th} horizontal voltage line HVLj may be located between the j^{th} driving scan line SCLj and the (j+1)^{th} sensing scan line SSLj+1 (e.g., in plan view). A separation distance (that is, the separation distance in the second direction DR2) ds1 between the j^{th} driving scan line SCLj and the (j+1)^{th} sensing scan line SSLj+1 may be greater than a width w1 of the j^{th} horizontal voltage line HVLj in the second direction DR2. Accordingly, the j^{th} driving scan line SCLj, the (j+1)^{th} sensing scan line SSLj+1, and the j^{th} horizontal voltage line HVLj do not overlap each other when viewed from above the plane (hereinafter, referred to as a “non-overlapping structure”). However, the present disclosure is not limited thereto. For example, the j^{th} driving scan line SCLj, the (j+1)^{th} sensing scan line SSLj+1, and the j^{th} horizontal voltage line HVLj may overlap each other when viewed from above the plane (hereinafter, referred to as having an “overlapping structure”).

FIG. 8C is an enlarged view of portion AA of FIG. 7 according to one or more embodiments of the present disclosure, and FIG. 8D is a sectional view taken along the line II-II′ illustrated in FIG. 8C.

Referring to FIGS. 8C and 8D, in the second non-emissive area A2, the j^{th} driving scan line SCLj, the (j+1)^{th} sensing scan line SSLj+1, and the j^{th} horizontal voltage line HVLj may overlap each other. In contrast, in the first non-emissive area A1, the j^{th} driving scan line SCLj, the (j+1)^{th} sensing scan line SSLj+1, and the j^{th} horizontal voltage line HVLj do not overlap each other.

The j^{th} horizontal voltage line HVLj may be located between the j^{th} driving scan line SCLj and the (j+1)^{th} sensing scan line SSLj+1 (e.g., in plan view). A separation distance (that is, the separation distance in the second direction DR2) ds2 between the j^{th} driving scan line SCLj and the (j+1)^{th} sensing scan line SSLj+1 may be less than the width w1 of the j^{th} horizontal voltage line HVLj in the second direction DR2. Accordingly, the j^{th} driving scan line SCLj, the (j+1)^{th} sensing scan line SSLj+1, and the j^{th} horizontal voltage line HVLj may overlap each other when viewed from above the plane.

When the j^{th} driving scan line SCLj and the (j+1)^{th} sensing scan line SSLj+1 overlap the j^{th} horizontal voltage line HVLj, the area of the transmissive area TA may be larger than that in the non-overlapping structure, and thus the transmittance of the display device DD may be improved.

When the j^{th} driving scan line SCLj and the (j+1)^{th} sensing scan line SSLj+1 are located on a layer that is different from the layer on which the j^{th} horizontal voltage line HVLj is located, the interval between the signal lines SCLj, HVLj, and SSLj+1 may be reduced, or the signal lines SCLj, HVLj, and SSLj+1 may be located to overlap each other. Accordingly, the area occupied by the signal lines SCLj, HVLj, and SSLj+1 in the display panel DP may be decreased. Thus, the area of the transmissive area TA may be increased, and the transmittance of the display panel DP may be improved.

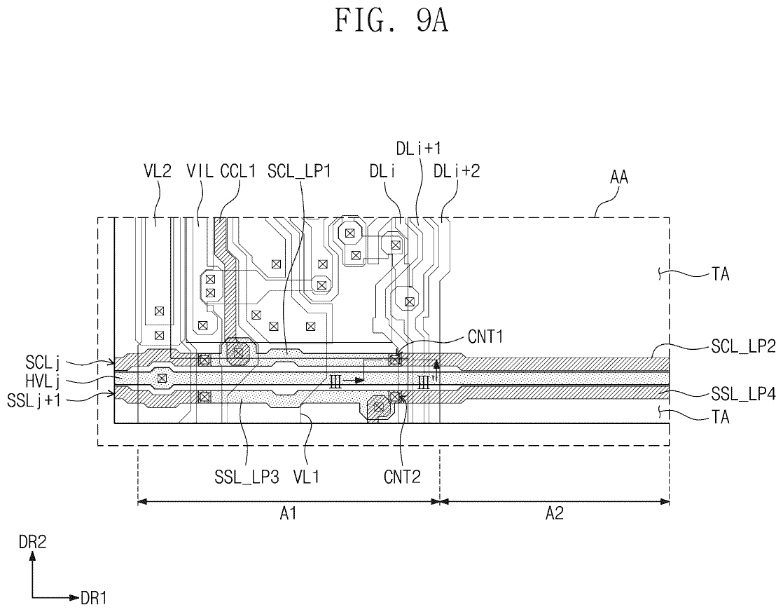

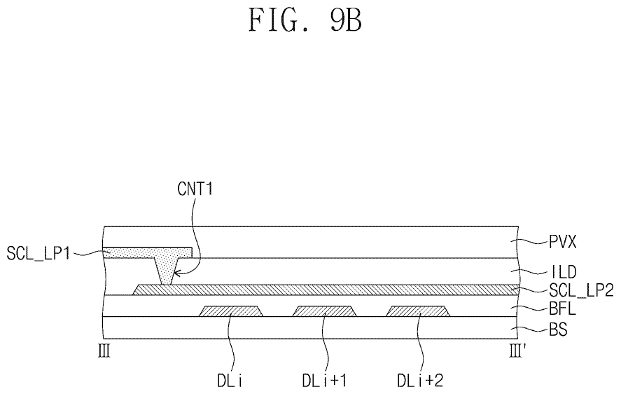

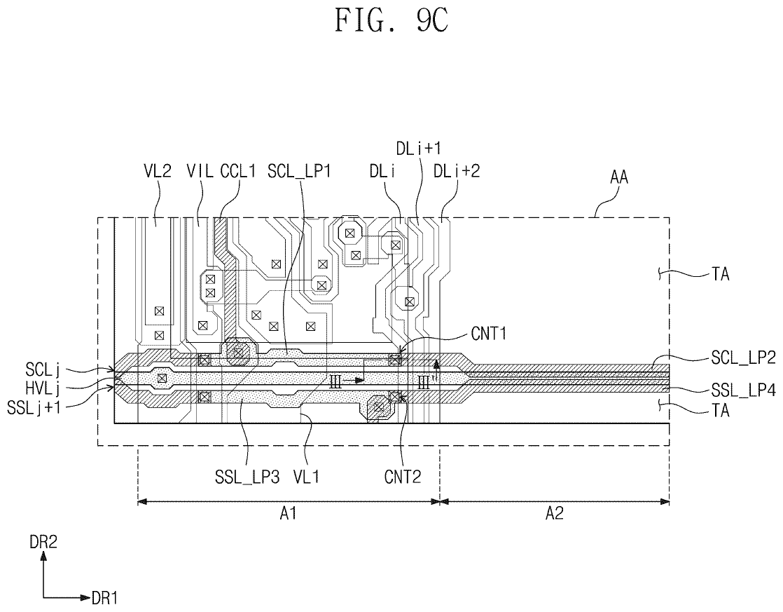

FIG. 9A is an enlarged view of portion AA of FIG. 7 according to one or more embodiments of the present disclosure. FIG. 9B is a sectional view taken along the line III-III′ illustrated in FIG. 9A. FIG. 9C is an enlarged view of portion AA of FIG. 7 according to one or more embodiments of the present disclosure.

1 Referring to FIGS. 9A and 9B, the j^{th} driving scan line SCLj, the (j+1)^{th} sensing scan line SSLj+1, and the j^{th} horizontal voltage line HVLj extend in the first direction DR1, and are spaced apart from each other in the second direction DR2. In one or more embodiments of the present disclosure, the j^{th} horizontal voltage line HVLj is located between the j^{th} driving scan line SCLj and the (j+1)^{th} sensing scan line SSLj+1.

The j^{th} driving scan line SCLj includes a first line portion SCL_LP1 and a second line portion SCL_LP2. The first line portion SCL_LP1 overlaps the first non-emissive area A1, and is located on a layer that is the same as the layer on which the j^{th} horizontal voltage line HVLj is located. The second line portion SCL_LP2 overlaps the second non-emissive area A2, and is located on a layer that is different from the layer on which the j^{th} horizontal voltage line HVLj is located. The first line portion SCL_LP1 and the second line portion SCL_LP2 may be connected through a first contact hole CNT1. In one or more embodiments of the present disclosure, the first line portion SCL_LP1 may be located on the inter insulating layer ILD, the second line portion SCL_LP2 may be located on the buffer layer BFL, and the first and second line portions SCL_LP1 and SCL_LP2 may be connected through the first contact hole CNT1 formed through the inter insulating layer ILD.

The j^{th} sensing scan line SSLj includes a third line portion SSL_LP3 and a fourth line portion SSL_LP4. The third line portion SSL_LP3 overlaps the first non-emissive area A1, and is located on a layer that is the same as the layer on which the j^{th} horizontal voltage line HVLj is located. The fourth line portion SSL_LP4 overlaps the second non-emissive area A2, and is located on a layer that is different from the layer on which the j^{th} horizontal voltage line HVLj is located. The third line portion SSL_LP3 and the fourth line portion SSL_LP4 may be connected through a second contact hole CNT2. In one or more embodiments of the present disclosure, the third line portion SSL_LP3 may be located on the inter insulating layer ILD, the fourth line portion SSL_LP4 may be located on the buffer layer BFL, and the third and fourth line portions SSL_LP3 and SSL_LP4 may be connected through the second contact hole CNT2 formed through the inter insulating layer ILD.

In the first non-emissive area A1, the first line portion SCL_LP1 and the third line portion SSL_LP3 are spaced apart from each other at a third interval in the second direction DR2. In the second non-emissive area A2, the second line portion SCL_LP2 and the fourth line portion SSL_LP4 are spaced apart from each other at a fourth interval in the second direction DR2. Here, the fourth interval is smaller than the third interval.

The structure in which the first line portion SCL_LP1 is located on the inter insulating layer ILD and the second line portion SCL_LP2 is located on the buffer layer BFL is illustrated in FIG. 9B. However, the present disclosure is not limited thereto. For example, the first and third line portions SCL_LP1 and SSL_LP3 may be located on the buffer layer BFL, and the second and fourth line portions SCL_LP2 and SSL_LP4 may be located on the inter insulating layer ILD.

In addition, the structure in which the j^{th} horizontal voltage line HVLj does not overlap the second and fourth line portions SCL_LP2 and SSL_LP4 is illustrated in FIG. 9A. However, the present disclosure is not limited thereto. For example, the j^{th} horizontal voltage line HVLj may overlap the second and fourth line portions SCL_LP2 and SSL_LP4 when viewed from above the plane.

Referring to FIG. 9C, in the second non-emissive area A2, the j^{th} horizontal voltage line HVLj may overlap the second and fourth line portions SCL_LP2 and SSL_LP4 when viewed from above the plane. In contrast, in the first non-emissive area A1, the j^{th} horizontal voltage line HVLj does not overlap the first and third line portions SCL_LP1 and SSL_LP3 when viewed from above the plane.

The separation distance (that is, the separation distance in the second direction DR2) between the second and fourth line portions SCL_LP2 and SSL_LP4 may be less than the width of the j^{th} horizontal voltage line HVLj. When the second and fourth line portions SCL_LP2 and SSL_LP4 overlap the j^{th} horizontal voltage line HVLj, the area of the transmissive area TA may be larger than that in the non-overlapping structure, and thus the transmittance of the display device DD may be improved.

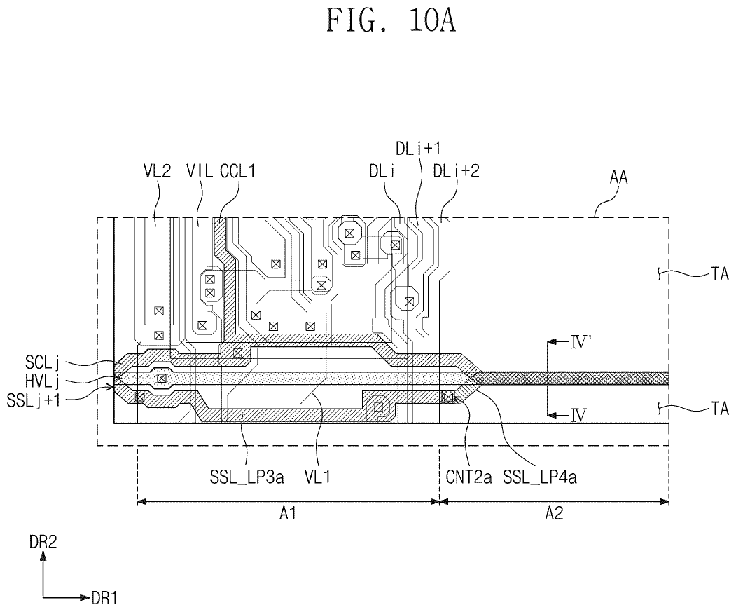

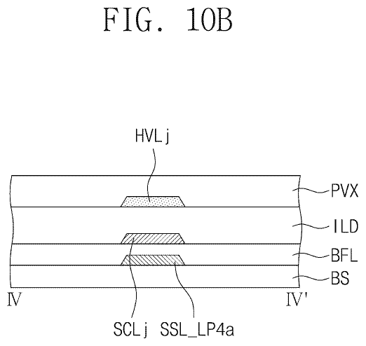

FIG. 10A is an enlarged view of portion AA of FIG. 7 according to one or more embodiments of the present disclosure, and FIG. 10B is a sectional view taken along the line IV-IV′ illustrated in FIG. 10A.

Referring to FIGS. 10A and 10B, the j^{th} horizontal voltage line HVLj is located between the j^{th} driving scan line SCLj and the (j+1)^{th} sensing scan line SSLj+1. The j^{th} horizontal voltage line HVLj is located on a layer that is different from the layer on which the j^{th} driving scan line SCLj and the (j+1)^{th} sensing scan line SSLj+1 are located.

In one or more embodiments of the present disclosure, the j^{th} driving scan line SCLj is located on the buffer layer BFL, and the j^{th} horizontal voltage line HVLj is located on the inter insulating layer ILD. The (j+1)^{th} sensing scan line SSLj+1 includes a third line portion SSL_LP3a and a fourth line portion SSL_LP4a. The third line portion SSL_LP3a overlaps the first non-emissive area A1, and is located on a layer that is the same as the layer on which the j^{th} driving scan line SCLj is located (e.g., the buffer layer BFL). The fourth line portion SSL_LP4a overlaps the second non-emissive area A2, and is located on a layer that is different from the layer on which the j^{th} driving scan line SCLj and the j^{th} horizontal voltage line HVLj are located. In one or more embodiments of the present disclosure, the fourth line portion SSL_LP4a may be located on the base layer BS. The fourth line portion SSL_LP4a and the first to third data lines DL1, DLi+1, and DLi+2 may be located on the same layer.

The third line portion SSL_LP3a and the fourth line portion SSL_LP4a may be connected through a second contact hole CNT2a. In one or more embodiments of the present disclosure, the third and fourth line portions SSL_LP3a and SSL_LP4a may be connected through the second contact hole CNT2a formed through the buffer layer BFL.

The fourth line portion SSL_LP4a may completely overlap the j^{th} driving scan line SCLj and the j^{th} horizontal voltage line HVLj when viewed from above the plane. Accordingly, when the fourth line portion SSL_LP4a, the j^{th} driving scan line SCLj, and the j^{th} horizontal voltage line HVLj are located on different layers, the three signal lines SCLj, HVLj, and SSLj+1 may be located in an area occupied by one signal line. Thus, the area of the transmissive area TA may be increased, and the transmittance of the display panel DP may be improved.

FIGS. 11A to 11F are process views illustrating a manufacturing process of the display panel according to one or more embodiments of the present disclosure.

Referring to FIGS. 6 and 11A, the light-blocking pattern layer BML is formed on the base layer BS. In one or more embodiments of the present disclosure, the light-blocking pattern layer BML may include a conductive material having light-blocking properties. The light-blocking pattern layer BML may include the shielding electrode BSE. The shielding electrode BSE may overlap a semiconductor pattern of at least one of transistors (that is, the first to third transistors T1 to T3 (refer to FIG. 5)) included in each of the first to third pixel circuits SPC1 to SPC3.

The light-blocking pattern layer BML may further include the first to third data lines DLi, DLi+1, and DLi+2. The first to third data lines DLi, DLi+1, and DLi+2 may extend in the second direction DR2, and may be spaced apart from each other in the first direction DR1. The light-blocking pattern layer BML may include a first vertical voltage line B_VL1, a second vertical voltage line B_VL2, and a first initialization voltage line B_VIL. The first vertical voltage line B_VL1, the second vertical voltage line B_VL2, and the first initialization voltage line B_VIL may extend in the second direction DR2, and may be spaced apart from each other in the first direction DR1. The shielding electrode BSE may be located between the first vertical voltage line B_VL1 and the first data line DLi. The first vertical voltage line B_VL1 may be included in the first voltage line VL1 illustrated in FIG. 4, the second vertical voltage line B_VL2 may be included in the second voltage line VL2 illustrated in FIG. 4, and the first initialization voltage line B_VIL may be included in the initialization voltage line VIL illustrated in FIG. 4.

Referring to FIGS. 6, 11A, and 11B, the light-blocking pattern layer BML is covered by the buffer layer BFL, and a semiconductor pattern layer is formed on the buffer layer BFL. The semiconductor pattern layer may include a plurality of semiconductor patterns OSL. Each of the semiconductor patterns OSL may be a semiconductor pattern of at least one of the first to third transistors T1 to T3 (refer to FIG. 5).

Each of the semiconductor patterns OSL may include an oxide semiconductor. For example, the oxide semiconductor may include metal oxide of zinc (Zn), indium (In), gallium (Ga), tin (Sn), or titanium (Ti). Alternatively, the oxide semiconductor may include a mixture of metal, such as zinc (Zn), indium (In), gallium (Ga), tin (Sn), or titanium (Ti) or oxide thereof. The oxide semiconductor may include indium-tin oxide (ITO), indium-gallium-zinc oxide (IGZO), zinc oxide (ZnO), indium-zinc oxide (IZO), zinc-indium oxide (ZIO), indium oxide (InO), titanium oxide (TiO), indium-zinc-tin oxide (IZTO), or zinc-tin oxide (ZTO).

Referring to FIGS. 6, 11B, and 11C, the gate-insulating patterns GIL are located on the semiconductor pattern OSL or the buffer layer BFL. A part of the gate-insulating patterns GIL may overlap the channel area of the semiconductor pattern OSL.

The gate pattern layer GAT may be located on the gate-insulating patterns GIL. The gate pattern layer GAT may include the third electrode (or, the gate) GE of each of the first to third transistors T1 to T3 (refer to FIG. 5), a first intermediate voltage line G_VL2, and the first and second connection lines CCL1 and CCL2. The first intermediate voltage line G_VL2 and the first and second connection lines CCL1 and CCL2 may extend in the second direction DR2. In one or more embodiments of the present disclosure, the gate pattern layer GAT may further include the (j−1)^{th} driving scan line SCLj−1, the j^{th} driving scan line SCLj, the j^{th} sensing scan line SSLj, and the (j+1)^{th} sensing scan line SSLj+1. The first connection line CCL1 branches off from the j^{th} driving scan line SCLj, and the second connection line CCL2 branches off from the j^{th} sensing scan line SSLj. The first intermediate voltage line G_VL2 overlaps the second vertical voltage line B_VL2 when viewed from above the plane. The first intermediate voltage line G_VL2 may be electrically connected with the second vertical voltage line B_VL2 to form the second voltage line VL2 (refer to FIG. 4).

Referring to FIGS. 6, 11C, and 11D, the inter insulating layer ILD is located on the buffer layer BFL to cover the gate pattern layer GAT. The data pattern layer SD may be located on the inter insulating layer ILD. The data pattern layer SD may include a connection electrode CCE, the (j−1)^{th} horizontal voltage line HVLj−1, and the j^{th} horizontal voltage line HVLj. The connection electrode CCE may be connected to the source area and the drain area of the semiconductor pattern OSL through contact holes penetrating the inter insulating layer ILD. The connection electrode CCE may include the first and second connection electrodes CCE1 and CCE2 illustrated in FIG. 6.

The data pattern layer SD may further include a second intermediate voltage line S_VL1, a third intermediate voltage line S_VL2, and a second initialization voltage line S_VIL. The second intermediate voltage line S_VL1 overlaps the first vertical voltage line B_VL1 when viewed from above the plane. The second intermediate voltage line S_VL1 may be electrically connected with the first vertical voltage line B_VL1 to form the first voltage line VL1 (refer to FIG. 4). The third intermediate voltage line S_VL2 may be electrically connected with the second vertical voltage line B_VL2 and the first intermediate voltage line G_VL2 to form the second voltage line VL2 (refer to FIG. 4). The second initialization voltage line S_VIL may be electrically connected with the first initialization voltage line B_VIL to form the initialization voltage line VIL (refer to FIG. 4).

Referring to FIGS. 6, 11D, and 11E, the protective layer PVX may be located on the inter insulating layer ILD to cover the data pattern layer SD, and the via layer VIA may be located on the protective layer PVX. The first to third anodes AE1, AE2, and AE3 of the first to third light-emitting elements ED1, ED2, and ED3 (refer to FIG. 5) may be located on the via layer VIA. The first to third anodes AE1, AE2, and AE3 may be connected to the connection electrode CCE through contact holes that penetrate the via layer VIA and the protective layer PVX. The first to third anodes AE1, AE2, and AE3 may be spaced apart from each other in the second direction DR2, and may be electrically insulated from each other.

A cathode connection electrode C_CNE may be located on the via layer VIA. The cathode connection electrode C_CNE may be an electrode for electrically connecting the cathode and the second voltage line VL2. In one or more embodiments of the present disclosure, the cathode connection electrode C_CNE may be connected with the third intermediate voltage line S_VL2 through a contact hole that penetrates the via layer VIA and the protective layer PVX.

Referring to FIGS. 6, 11E, and 11F, the pixel-defining layer PDL may be located on the via layer VIA and may cover a portion of each of the first to third anodes AE1, AE2, and AE3. First to third openings PDL_OP1, PDL_OP2, and PDL_OP3 are defined in the pixel-defining layer PDL. The first to third openings PDL_OP1, PDL_OP2, and PDL_OP3 of the pixel-defining layer PDL expose at least portions of the first to third anodes AE1, AE2, and AE3, respectively.

The pixel-defining layer PDL may further include an opening C_OP that exposes a portion of the cathode connection electrode C_CNE. The opening C_OP may be a portion on which a laser drilling process for connection the cathode and the second voltage line VL2 is performed.

According to the present disclosure, when the driving scan line and the sensing scan line are located on a layer that is different from the layer on which the horizontal voltage line is located, the intervals between the signal lines may be reduced, or the signal lines may be located to overlap each other. Accordingly, the area occupied by the signal lines in the display panel may be decreased. Thus, the 1 area of the transmissive area may be increased, and the transmittance of the display panel may be improved.

While the present disclosure has been described with reference to embodiments thereof, it will be apparent to those of ordinary skill in the art that various changes and modifications may be made thereto without departing from the spirit and scope of the present disclosure as set forth in the following claims, with functional equivalents thereof to be included therein.

What is claimed is:

1. A display device comprising:
a pixel having a transmissive area configured to transmit external light, and a non-transmissive area configured to block external light and comprising an emissive area, a first non-emissive area between two adjacent emissive areas, and a second non-emissive area between two adjacent transmissive areas;
a driving scan line connected to the pixel, and extending in a first direction;
a sensing scan line connected to the pixel, and extending in the first direction; and
a horizontal voltage line connected to the pixel, and extending in the first direction,
wherein, in the first non-emissive area, the driving scan line, the sensing scan line, and the horizontal voltage line are spaced from each other at a first interval in a second direction crossing the first direction, and
wherein, in the second non-emissive area, the driving scan line, the sensing scan line, and the horizontal voltage line either overlap each other or are spaced from each other at a second interval in the second direction that is smaller than the first interval.

2. The display device of claim 1, wherein the first non-emissive area comprises:
a first sub-area where the driving scan line, the sensing scan line, and the horizontal voltage line are spaced from each other at the first interval; and
a second sub-area where the driving scan line, the sensing scan line, and the horizontal voltage line either overlap each other or are spaced from each other at the second interval.

3. The display device of claim 2, wherein the second sub-area is between the first sub-area and the second non-emissive area.

4. The display device of claim 1, wherein the horizontal voltage line is between the driving scan line and the sensing scan line in plan view, and
wherein a separation distance between the driving scan line and the sensing scan line is greater than a width of the horizontal voltage line.

5. The display device of claim 4, wherein the horizontal voltage line is on a different layer than the driving scan line and the sensing scan line.

6. The display device of claim 5, wherein a gate pattern layer comprises the driving scan line and the sensing scan line, and
wherein a data pattern layer comprises the horizontal voltage line.

7. The display device of claim 1, wherein the horizontal voltage line is between the driving scan line and the sensing scan line in plan view, and
wherein a separation distance between the driving scan line and the sensing scan line is less than a width of the horizontal voltage line.

8. The display device of claim 1, further comprising:
a first voltage line connected to the pixel, and extending in the second direction; and
a second voltage line connected to the pixel, extending in the second direction, and spaced from the first voltage line in the first direction,
wherein the horizontal voltage line is connected to the first voltage line or the second voltage line.

9. The display device of claim 1, wherein the horizontal voltage line is between the driving scan line and the sensing scan line in plan view,
wherein the driving scan line comprises a first line portion on a same layer as the horizontal voltage line in the first non-emissive area, and a second line portion on a different layer from the horizontal voltage line in the second non-emissive area, and
wherein the sensing scan line comprises a third line portion on a same layer as the horizontal voltage line in the first non-emissive area, and a fourth line portion on a different layer from the horizontal voltage line in the second non-emissive area.

10. The display device of claim 9, wherein a separation distance between the second line portion and the fourth line portion is less than a separation distance between the first line portion and the third line portion.

11. The display device of claim 9, wherein the first line portion is connected with the second line portion through a first contact hole, and
wherein the third line portion is connected with the fourth line portion through a second contact hole.

12. The display device of claim 1, wherein the pixel comprises:
a first sub-pixel configured to output light of a first color;
a second sub-pixel configured to output light of a second color; and
a third sub-pixel configured to output light of a third color.

13. The display device of claim 12, further comprising:
a first data line connected to the first sub-pixel, and extending in the second direction;
a second data line connected to the second sub-pixel, and extending in the second direction; and
a third data line connected to the third sub-pixel, and extending in the second direction,
wherein the first data line, the second data line, and the third data line overlap the first non-emissive area.

14. The display device of claim 13, wherein the first data line, the second data line, and the third data line are on a different layer than the driving scan line, the sensing scan line, and the horizontal voltage line.

15. The display device of claim 13, wherein the driving scan line and the horizontal voltage line are on a different layer than the first data line, the second data line, and the third data line,
wherein the sensing scan line comprises a third line portion in the first non-emissive area on a same layer as the driving scan line, and a fourth line portion in the second non-emissive area on a same layer as the first data line, as the second data line, and as the third data line, and
wherein the third line portion is connected with the fourth line portion through a second contact hole.

16. The display device of claim 15, wherein the driving scan line, the fourth line portion of the sensing scan line, and the horizontal voltage line overlap each other.

17. The display device of claim 13, further comprising:
a first voltage line connected to the pixel, and extending in the second direction; and
a second voltage line connected to the pixel, extending in the second direction, and spaced from the first voltage line in the first direction, wherein the first voltage line and the second voltage line are on a same layer as the first data line, the second data line, and the third data line.

18. The display device of claim 12, further comprising:
a first connection line connecting the driving scan line to the first sub-pixel, the second sub-pixel, and the third sub-pixel; and
a second connection line connecting the sensing scan line to the first sub-pixel, the second sub-pixel, and the third sub-pixel.

19. The display device of claim 18, wherein the first and second connection lines are on a same layer as the driving scan line and the sensing scan line, and wherein the first and second connection lines are on a different layer than the horizontal voltage line.

20. A display device comprising:
a base layer;
a buffer layer above the base layer;
an inter insulating layer above the buffer layer;
a pixel above the base layer, and having a non-transmissive area for blocking external light and a transmissive area for transmitting external light;
a driving scan line connected to the pixel, and extending in a first direction;
a sensing scan line connected to the pixel, and extending in the first direction;
a horizontal voltage line connected to the pixel, and extending in the first direction;
a data line connected to the pixel, and extending in a second direction crossing the first direction;
a light-blocking pattern layer above the base layer, and comprising the data line;
a gate pattern layer above the buffer layer, configured to cover the light-blocking pattern layer, and comprising two of the driving scan line, the sensing scan line, or the horizontal voltage line; and
a data pattern layer above the inter insulating layer, configured to cover the gate pattern layer, and comprising a remaining one of the driving scan line, the sensing scan line, or the horizontal voltage line.

21. The display device of claim 20, wherein the horizontal voltage line is between the driving scan line and the sensing scan line in plan view, and
wherein a separation distance between the driving scan line and the sensing scan line is greater than a width of the horizontal voltage line in the second direction.

22. The display device of claim 21, wherein the horizontal voltage line is on a different layer than the driving scan line and the sensing scan line.

23. The display device of claim 22, wherein the gate pattern layer comprises the driving scan line and the sensing scan line, and
wherein the data pattern layer comprises the horizontal voltage line.

24. The display device of claim 20, wherein the horizontal voltage line is between the driving scan line and the sensing scan line in plan view, and
wherein a separation distance between the driving scan line and the sensing scan line is less than a width of the horizontal voltage line in the second direction.

25. The display device of claim 20, further comprising:
a first voltage line connected to the pixel, and extending in the second direction; and
a second voltage line connected to the pixel, extending in the second direction, and spaced from the first voltage line in the first direction,
wherein the horizontal voltage line is connected to the first voltage line or the second voltage line.

26. The display device of claim 20, wherein the pixel comprises:
a first sub-pixel configured to output light of a first color;
a second sub-pixel configured to output light of a second color; and
a third sub-pixel configured to output light of a third color.

27. The display device of claim 26, further comprising:
a first data line connected to the first sub-pixel, and extending in the second direction;
a second data line connected to the second sub-pixel, and extending in the second direction; and
a third data line connected to the third sub-pixel, and extending in the second direction,
wherein the first data line, the second data line, and the third data line overlap the non-transmissive area.

28. The display device of claim 27, wherein the first data line, the second data line, and the third data line are on a different layer than the driving scan line, the sensing scan line, and the horizontal voltage line.

29. The display device of claim 27, further comprising:
a first voltage line connected to the pixel, and extending in the second direction; and
a second voltage line connected to the pixel, extending in the second direction, and spaced from the first voltage line in the first direction,
wherein the first voltage line and the second voltage line are on a same layer as the first data line, the second data line, and the third data line.

30. The display device of claim 26, further comprising:
a first connection line connecting the driving scan line to the first sub-pixel, the second sub-pixel, and the third sub-pixel; and
a second connection line connecting the sensing scan line to the first sub-pixel, the second sub-pixel, and the third sub-pixel,
wherein the first connection line and the second connection line are on a same layer as the driving scan line and the sensing scan line, and
wherein the first connection line and the second connection line are on a different layer than the horizontal voltage line.
